(19) United States
(12) Patent Application Publication
(10) Pub. No.: US 2023/0136499 A1
(43) Pub. Date: May 4, 2023

(54) Selective Passivation Of Damaged Nitride

(71) Applicant: Applied Materials, Inc., Santa Clara, CA (US)

(72) Inventors: Shumao Zhang, San Jose, CA (US); Bhaskar Jyoti Bhuyan, San Jose, CA (US); Aaron Dangerfield, San Jose, CA (US); Jesus Candelario Mendoza-Gutierrez, San Jose, CA (US); Le Zhang, Fremont, CA (US); David T. Or, Santa Clara, CA (US); Mark Saly, Santa Clara, CA (US); Jiang Lu, Milpitas, CA (US)

(73) Assignee: Applied Materials, Inc., Santa Clara, CA (US)

(21) Appl. No.: 17/844,185

(22) Filed: Jun. 20, 2022

Related U.S. Application Data
(60) Provisional application No. 63/273,990, filed on Oct. 31, 2021.

(51) Int. Cl. H01L 21/02

(52) U.S. Cl. CPC H01L 21/02271; H01L 21/02068; H01L 21/0217; H01L 21/02219; H01L 21/02211

(57) ABSTRACT

Methods for selectively depositing on self-assembled monolayer (SAM) are disclosed. Some embodiments of the disclosure utilize a precursor of a Formula (I), Formula (II), Formula (III), and Formula (IV):

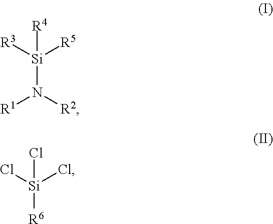

RₙSi(NR′R″)₍₄₋ₙ₎ (III), RₙSiX₍₄₋ₙ₎ (IV),
wherein R¹ and R² are independently selected from substituted or unsubstituted C₁-C₂₀ alkyl, or R¹ and R² form a substituted or unsubstituted C₁-C₂₀ cycloalkyl ring, and wherein R³, R⁴, R⁵, R⁶, Rₙ are independently selected from hydrogen, substituted or unsubstituted C₁-C₂₀ alkyl, substituted or unsubstituted C₁-C₂₀ alkoxy, and substituted or unsubstituted C₁-C₂₀ vinyl, X is a halide selected from Cl, Br, and I, and n is an integer from 1 to 3, to form a self-assembled monolayer (SAM) on a damaged silicon nitride layer to prevent critical dimension blow out of a feature in a silicon nitride layer substrate.

### CROSS-REFERENCE TO RELATED APPLICATIONS

This application claims priority to United States Provisional Application No. 63/273,990, filed Oct. 31, 2021, the entire disclosure of which is hereby incorporated by reference herein.

### TECHNICAL FIELD

Embodiments of the disclosure generally relate to methods of forming a semiconductor structure. More particularly, some embodiments of the disclosure are directed to methods of depositing a passivation layer on a substrate to preserve the critical dimension of a substrate feature.

### BACKGROUND

Generally, an integrated circuit (IC) refers to a set of electronic devices, e.g., transistors formed on a small chip of semiconductor material, typically, silicon. Typically, the IC includes one or more layers of metallization having metal lines to connect the electronic devices of the IC to one another and to external connections. Typically, layers of the interlayer dielectric material are placed between the metallization layers of the IC for insulation.

Semiconductor processing is often guided by ever decreasing node sizes. As the node advances along Moore's law, semiconductor devices as well as the critical dimension (CD) and pitch sizes in the chip have become smaller. Pre-clean and/or etching processes can lead to sidewall dielectric loss and significantly increase the critical dimension of a feature, which is problematic for manufacturers who need to minimize the dimension changes in the structure.

Preserving the critical dimension of the structure is critical for improved performance of the electronic device. Thus, there is a need for a method of maintaining the critical dimensions of a semiconductor structure.

### SUMMARY

One or more embodiments of the disclosure are directed to a method of forming a semiconductor structure. In some embodiments, the method comprises depositing a passivation layer on a substrate, the substrate comprising a silicon nitride layer including at least one feature formed therein, the at least one feature having a first width and having a top surface, a bottom surface, and at least one sidewall surface, wherein a damaged silicon nitride layer is on the top surface and on the at least one sidewall surface, and a silicon oxide layer is on the bottom surface; and pre-cleaning the substrate to remove the damaged silicon nitride layer from the top surface and the silicon oxide layer from the bottom surface.

In one or more embodiments, the method comprises depositing a passivation layer on a substrate by exposing the substrate to a precursor, the substrate comprising a silicon nitride layer including at least one feature formed therein, the at least one feature having a first width and having a top surface, a bottom surface, and at least one sidewall surface, wherein a damaged silicon nitride layer is on the top surface and on the at least one sidewall surface, and a silicon oxide layer is on the bottom surface; and pre-cleaning the substrate to remove the damaged silicon nitride layer from the top surface and the silicon oxide layer from the bottom surface, wherein the precursor comprises a compound according to Formula (I) and Formula (III)

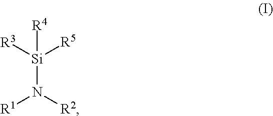

RₙSi(NR′R″)₍₄₋ₙ₎ (III), wherein R¹ and R² are independently selected from substituted or unsubstituted C₁-C₂₀ alkyl, or R¹ and R² form a substituted or unsubstituted C₁-C₂₀ cycloalkyl ring, and wherein R³, R⁴, R⁵, Rₙ are independently selected from hydrogen, substituted or unsubstituted C₁-C₂₀ alkyl, substituted or unsubstituted C₁-C₂₀ alkoxy, and substituted or unsubstituted C₁-C₂₀ vinyl, and n is an integer from 1 to 3.

In one or more embodiments, the method comprises selectively depositing a passivation layer on a substrate by exposing the substrate to a precursor, the substrate comprising a silicon nitride layer and including at least one feature formed therein, the at least one feature having a first width and having a top surface, a bottom surface, and at least one sidewall surface, wherein a damaged silicon nitride layer is on the top surface and on the at least one sidewall surface, and a silicon oxide layer is on the bottom surface; and pre-cleaning the substrate to remove the damaged silicon nitride layer from the top surface and remove the silicon oxide layer from the bottom surface, wherein the precursor comprises a compound according to Formula (II) and Formula (IV),

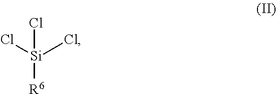

RₙSiX₍₄₋ₙ₎ (IV), wherein R⁶ and Rₙ are independently selected from hydrogen, substituted or unsubstituted C₁-C₂₀ alkyl, substituted or unsubstituted C₁-C₂₀ alkoxy, and substituted or unsubstituted C₁-C₂₀ vinyl, X is a halide selected from Cl, Br, and I, and n is an integer from 1 to 3.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 illustrates a process flow diagram of a method according to one or more embodiments of the disclosure;

FIGS. 2A-2F illustrate cross-sectional views of an exemplary substrate during processing according to one or more embodiments of the disclosure; and

FIG. 3 illustrates an exemplary cluster tool according to one or more embodiments of the disclosure.

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

As used in this specification and the appended claims, the term “substrate” refers to a surface, or portion of a surface, upon which a process acts. It will also be understood by those skilled in the art that reference to a substrate can also refer to only a portion of the substrate unless the context clearly indicates otherwise. Additionally, reference to depositing on a substrate can mean both a bare substrate and a substrate with one or more films or features deposited or formed thereon

A “substrate” as used herein, refers to any substrate or material surface formed on a substrate upon which film processing is performed during a fabrication process. For example, a substrate surface on which processing can be performed include materials such as silicon, silicon oxide, strained silicon, silicon on insulator (SOI), carbon doped silicon oxides, amorphous silicon, doped silicon, germanium, gallium arsenide, glass, sapphire, and any other materials such as metals, metal nitrides, metal alloys, and other conductive materials, depending on the application. Substrates include, without limitation, semiconductor wafers. Substrates may be exposed to a pretreatment process to polish, etch, reduce, oxidize, hydroxylate, anneal, UV cure, e-beam cure and/or bake the substrate surface. In addition to film processing directly on the surface of the substrate itself, in the present disclosure, any of the film processing steps disclosed may also be performed on an underlayer formed on the substrate as disclosed in more detail below, and the term “substrate surface” is intended to include such underlayer as the context indicates. Thus, for example, where a film/layer or partial film/layer has been deposited onto a substrate surface, the exposed surface of the newly deposited film/layer becomes the substrate surface.

“Atomic layer deposition” or “cyclical deposition” as used herein refers to the sequential exposure of two or more reactive compounds to deposit a layer of material on a substrate surface. As used in this specification and the appended claims, the terms “reactive compound”, “reactive gas”, “reactive species”, “precursor”, “process gas” and the like are used interchangeably to mean a substance with a species capable of reacting with the substrate surface or material on the substrate surface in a surface reaction (e.g., chemisorption, oxidation, reduction). The substrate, or portion of the substrate, is exposed to the precursors (or reactive gases) sequentially or substantially sequentially. As used herein throughout the specification, “substantially sequentially” means that a majority of the duration of a precursor exposure does not overlap with the exposure to a co-reagent, although there may be some overlap.

The phrase “selectively depositing on a first surface over a second surface”, and the like, as used herein means that a first amount or thickness is deposited on the first surface and a second amount or thickness is deposited on the second surface, where the second amount or thickness is less than the first amount or thickness, or, in some embodiments, no amount is deposited on the second surface.

The term “over” as used herein does not imply a physical orientation of one surface on top of another surface, rather a relationship of the thermodynamic or kinetic properties of the chemical reaction with one surface relative to the other surface. For example, selectively depositing a film onto a damaged dielectric material over an oxide material means that the film deposits on the damaged dielectric material and less or no film deposits on the oxide material; or that the formation of the film on the damaged dielectric material is thermodynamically or kinetically favorable relative to the formation of a film on the oxide material.

Reducing contact resistance (Rc) for advanced semiconductor devices is critical. Oxide removal before silicidation is important to reduce the junction contact resistance of a semiconductor device. In a semiconductor device, an epitaxial silicon structure is located at the bottom of the device with a dielectric material, such as silicon nitride (SiN), on top of the epitaxial silicon. A feature may be formed in the dielectric material such that the bottom of the feature is comprised of the epitaxial silicon and the dielectric material, e.g., SiN, comprises the sidewall surfaces of the feature. The sidewall dielectric material can be damaged, for example by oxidation or ion bombardment, which creates more dangling bonds, from upstream processes or vacuum break prior to silicide formation. In one or more embodiments, the damaged silicon nitride or oxynitride surface is from upstream fabrication flow, which causes chemical elemental change or physical ion bombardment on a surface. In embodiments where the sidewall dielectric material is silicon nitride (SiN), the damaged surface is comprised of silicon oxynitride (SiON) and/or silicon oxide (SiOₓ). When the oxidized silicon layer on the epitaxial silicon is then removed, the damaged material (SiON) and some of the underlying sidewall silicon nitride material is also removed, which will cause significant, e.g., >30%, critical dimension (CD) blowout and yield loss. Accordingly, one or more embodiments provide deposition of a passivation layer to passivate the dielectric layer over the oxide layer to solve the CD blowout issue. In some embodiments, the passivation process uses selective blocking self-assembled monolayer (SAM) chemistry.

Accordingly, one or more embodiments of this disclosure are directed to methods of selectively forming a self-assembled monolayer (SAM) on a first surface of a substrate over a second surface. The substrate comprises a silicon nitride material with a damaged first surface (e.g., SiON) and an epitaxial silicon layer with a silicon oxide (SiOₓ) second surface. In some embodiments, the method described herein have middle end of line (MEOL) and back end of line (BEOL) applications.

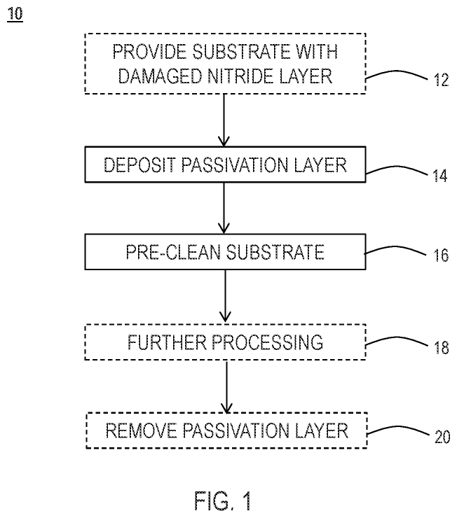

With reference to FIG. 1, which is a process flow diagram, one or more embodiments of the disclosure are directed to a method 10 of forming an electronic device. The method illustrated in FIG. 1 may be representative of an integrated process where vacuum conditions are maintained throughout processing.

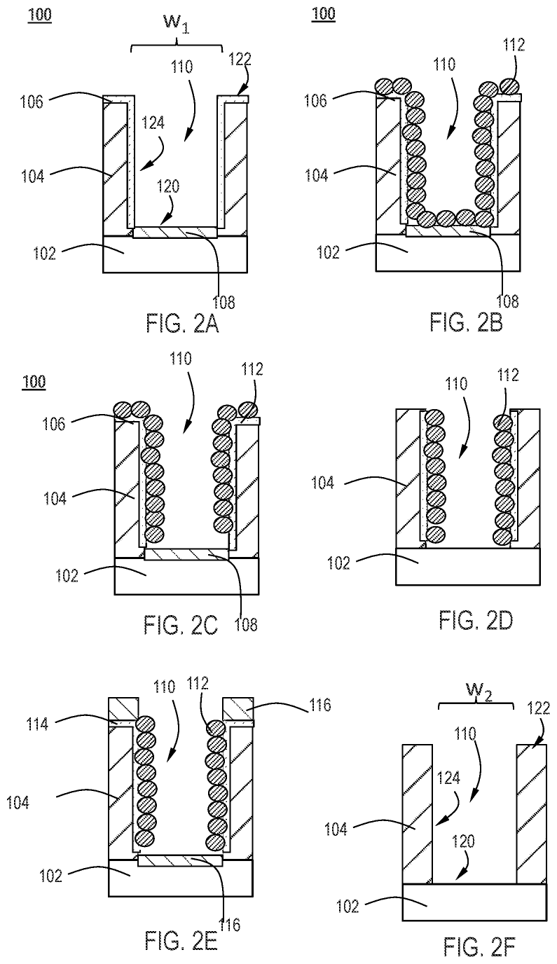

FIGS. 2A thru 2E illustrate cross-sectional views of an exemplary device during the processing method 10 according to one or more embodiments of the disclosure. Referring to FIG. 2A, a substrate 100 is provided for processing at operation 12. In some embodiments, the substrate 100 is a wafer, for example a semiconductor substrate. In one or more embodiments, the substrate 100 includes an epitaxial silicon layer 102 and a silicon nitride layer 104. In one or more embodiments, the silicon nitride layer 104 has at least one feature 110 formed therein.

In one or more embodiments, the silicon nitride layer 104 is deposited using any suitable deposition technique, such as, but not limited to, chemical vapor deposition (“CVD”), physical vapor deposition (“PVD”), molecular beam epitaxy (“MBE”), metalorganic chemical vapor deposition (“MOCVD”), atomic layer deposition (“ALD”), spin-on, or other deposition techniques known to one of ordinary skill in the art of microelectronic device manufacturing.

For illustrative purposes, FIG. 2A shows the substrate 100 having a single feature 110. One skilled in the art, however, will understand that there can be more than one feature. As shown in FIG. 2A, the feature 110 includes a top surface 122, a bottom surface 120, and at least one sidewall surface 124. The shape of the feature 110 can be any suitable shape including, but not limited to, trenches, vias that, when filled with metal, transfer current between layers, and lines that transfer current within the same device layer. In some embodiments, the feature 110 defines a gap in the dielectric layer (silicon nitride layer) 104. As used herein, the term “feature” refers to any intentional surface irregularity. Suitable examples of features include, but are not limited to, trenches which have a top, two sidewalls, and a bottom, peaks which have a top and two sidewalls. Features can have any suitable aspect ratio (ratio of the depth of the feature to the width of the feature). In some embodiments, the aspect ratio is greater than or equal to about 1:1, 2:1, 3:1, 4:1, 5:1, 10:1, 15:1, 20:1, 25:1, 30:1, 35:1 or 40:1.

Features can have any suitable critical dimension (CD). As used herein, the term “critical dimension (CD)” refers to the width of the feature or opening. In one or more embodiments, the critical dimension width, w₁, of the feature 110 is in a range of from 50 to 100 Å, or is in a range of from 50 to 75 Å, or is in a range of from 60 to 70 Å.

In one or more embodiments, the silicon nitride layer 104 is damaged during processing and a damaged layer 106 forms on the top surface 122 and the sidewalls 124 of the feature 110. In some embodiments, the damaged layer 106 comprises silicon oxynitride (SiON). In one or more embodiments, during processing, an oxide layer 108 may form on the epitaxial silicon layer 102. In some embodiments, the oxide layer 108 may be a native oxide layer that is formed upon exposure to the atmosphere during a vacuum break. The oxide layer 108 is the bottom surface 120 of the feature 110.

As used in this specification and the appended claims, the term “oxide” or the like means that the material contains the specified element(s). The term should not be interpreted to imply a specific ratio of elements. Accordingly, an “oxide” or the like may comprise a stoichiometric ratio of elements or a non-stoichiometric ratio of elements.

Without intending to be by bound by theory, if the device 100 of FIG. 2A were subjected to an etching process, CD blowout would result with a portion of the sidewall dielectric silicon nitride layer 104 being lost and the width of the feature 110 increasing. Such an increase in the critical dimension of the feature 110 would be undesirable to manufacturers.

Accordingly, referring to FIGS. 1 and 2B-2C, in one or more embodiments a passivation layer 112 is formed. In one or more embodiments, the passivation layer 112 is a self-assembled monolayer.

In some embodiments, as illustrated in FIG. 2B, deposition of the passivation layer 112 is non-selective, and the passivation layer 112 forms on the top surface 122, the bottom surface 120, and on the sidewall surface 124. With reference to FIG. 2C, in other embodiments, the deposition of the passivation layer 112 is selective, and the passivation layer 112 forms on the top surface 122 and the sidewall surface 124 but does not form on the bottom surface 120.

In some embodiments, “selectively” means that the subject material, e.g., the passivation layer 112, forms on the selected surface at a rate greater than or equal to about 1.5×, 2×, 3×, 4×, 5×, 7×, 10×, 15×, 20×, 25×, 30×, 35×, 40×, 45×, or 50× the rate of formation on the non-selected surface. Stated differently, the selectivity of the stated process for the selected surface relative to the non-selected surface is greater than or equal to about 3:2, 2:1, 3:1, 4:1, 5:1, 7:1, 10:1, 15:1, 20:1, 25:1, 301, 35:1, 40:1, 45:1, or 50:1.

In one or more embodiments, the passivation layer 112 is formed by exposing the substrate to a precursor to deposit a self-assembled monolayer (SAM). More specifically, at operation 14, the substrate 100 is exposed to a precursor to deposit a self-assembled monolayer (SAM) or passivation layer 112. As used herein, the phrase “the substrate is exposed to” means that the substrate, as a whole, including the individual materials and layers thereon are exposed to the stated process or condition.

In one or more embodiments, the precursor reversibly binds to the damaged layer 106. In some embodiments, the damaged layer 106 comprises silicon oxynitride having nitrogen and oxygen atoms to which the precursor can bind. In one or more embodiments, the oxide layer 108 has oxygen bonds to which the precursor can bind.

The precursor can comprise any suitable precursor known to the skilled artisan. In one or more embodiments, the precursor comprises a compound according to one or more of a Formula (I), Formula (II), Formula (III), and Formula (IV):

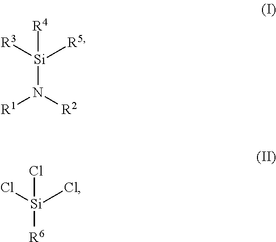

RₙSi(NR′R″)₍₄₋ₙ₎ (III), RₙSiX₍₄₋ₙ₎ (IV),

wherein R¹ and R² are independently selected from substituted or unsubstituted C₁-C₂₀ alkyl, or R¹ and R² form a substituted or unsubstituted C₁-C₂₀ cycloalkyl ring, and wherein R³, R⁴, R⁵, R⁶, Rₙ are independently selected from hydrogen, substituted or unsubstituted C₁-C₂₀ alkyl, substituted or unsubstituted C₁-C₂₀ alkoxy, and substituted or unsubstituted C₁-C₂₀ vinyl, X is a halide selected from Cl, Br, and I, and n is an integer from 1 to 3.

Unless otherwise indicated, the term “lower alkyl,” “alkyl,” or “alk” as used herein alone or as part of another group includes both straight and branched chain hydrocarbons, containing 1 to 20 carbons, in the normal chain, such as methyl, ethyl, propyl, isopropyl, butyl, t-butyl, isobutyl, pentyl, hexyl, isohexyl, heptyl, 4,4-dimethylpentyl, octyl, 2,2,4-trimethyl-pentyl, nonyl, decyl, undecyl, dodecyl, the various branched chain isomers thereof, and the like. Such groups may optionally include up to 1 to 4 substituents. The alkyl may be substituted or unsubstituted.

As used herein, the term “alkoxy” includes any of the above alkyl groups linked to an oxygen atom. The alkoxy may be substituted or unsubstituted.

As used herein, the terms “vinyl” or “vinyl-containing” refer to groups containing the vinyl group (—CH═CH₂). The vinyl may be substituted or unsubstituted.

As used herein, the term “silane” refers to a compound SiR′₃, wherein R′ is independently selected from hydrogen (H) or alkyl. The alkyl of the silane may be substituted or unsubstituted.

As used herein, the term “halide” refers to a binary phase, of which one part is a halogen atom and the other part is an element or radical that is less electronegative than the halogen, to make a fluoride, chloride, bromide, or iodide compound. A halide ion is a halogen atom bearing a negative charge. As known to those of skill in the art, a halide anion includes fluoride (F—), chloride (Cl—), bromide (Br—), and iodide (I—).

In one or more embodiments, the precursor of Formula (I) is selected from one or more of

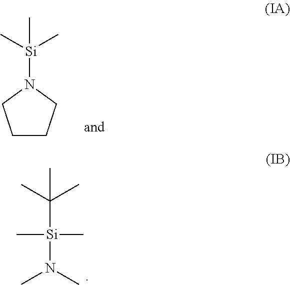

In one or more embodiments, the precursor of Formula (II) comprises

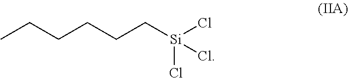

In one or more embodiments, the substrate 100 can be exposed to the precursor at any suitable flow rate to form the self-assembled monolayer (SAM) 112. In some embodiments, the substrate 100 is exposed to the precursor at a flow rate in a range of from 50 sccm to 2000 sccm, from 500 sccm to 2000 sccm, from 1000 sccm to 2000 sccm, from 50 sccm to 100 sccm. In some embodiments, the flow rate of the precursor is less than or equal to 2000 sccm, less than or equal to 1000 sccm, less than or equal to 500 sccm, less than or equal to 250 sccm, less than or equal to 100 sccm, or less than or equal to 50 sccm.

In some embodiments, the substrate 100 is soaked in a vapor of the precursor. In some embodiments, the soak period can be any suitable period for forming the self-assembled monolayer (SAM) 112. In some embodiments, the soak period is greater than or equal to 10 s, greater than or equal to 30 s, greater than or equal to 60 s, greater than or equal to 120 s, or greater than or equal to 200 s.

In one or more embodiments, the precursor is liquid at the operating temperature and/or operating pressure. In one or more embodiments, the precursor is solid at the operating temperature and/or operating pressure. In some embodiments, the precursor is stored in an ampoule or a cylinder, from which the precursor is delivered to the substrate 100. In some embodiments, the precursor has a vapor pressure in a range of from 0.1 Torr to 150 Torr, from 0.1 Torr to 50 Torr, from 0.1 Torr to 1 Torr, from 1 Torr to 150 Torr, from 1 Torr to 10 Torr, from 10 Torr to 150 Torr, from 50 Torr to 150 Torr, or from 100 Torr to 150 Torr at the operating temperature and/or operating pressure. In some embodiments, the precursor has a vapor pressure greater than or equal to about 0.1 Torr at the operating temperature and/or operating pressure.

In one or more embodiments, the precursor further comprises a carrier gas. In some embodiments, the carrier gas is a non-reactive gas. In some embodiments, the carrier gas comprises a noble gas. In some embodiments, the noble gas includes one or more of helium (He), neon (Ne), or argon (Ar). In some embodiments, the carrier gas comprises argon (Ar).

In some embodiments, a flow of the carrier gas is configured to carry the precursor from a container to the substrate 100. In some embodiments, the flow rate of the argon (Ar) gas that is configured to carry the precursor to the substrate 100 is controlled.

In some embodiments, the temperature of the substrate 100 is controlled during the method 10. The temperature of the substrate 100 may also be referred to as the operating temperature. In some embodiments, the operating temperature is less than or equal to 450° C., less than or equal to 400° C., less than or equal to 350° C., less than or equal to 300° C., less than or equal to 275° C., less than or equal to 250° C., less than or equal to 225° C., less than or equal to 200° C., less than or equal to 150° C., less than or equal to 100° C., or less than or equal to 80° C. In some embodiments, the operating temperature in a range of from 60° C. to 450° C., from 60° C. to 250° C., from 60° C. to 100° C., from 100° C. to 450° C., from 100° C. to 250° C., from 200° C. to 450° C., from 200° C. to 300° C., from 300° C. to 450° C., or from 400° C. to 450° C. during the deposition of the self-assembled monolayer (SAM) 112.

In one or more embodiments, a passivation layer 112 is deposited on the substrate 100 by exposing the substrate 100 to a precursor. In one or more embodiments, the deposition is non-selective such that the passivation layer 112 forms on the top surface 122, the bottom surface 120, and on the sidewall surface 124. In one or more embodiments, when the deposition is non-selective, the precursor comprises a compound according to Formula (I) and Formula (III)

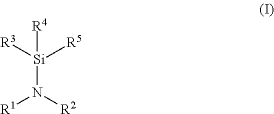

RₙSi(NR′R″)₍₄₋ₙ₎ (III),

wherein R¹ and R² are independently selected from substituted or unsubstituted C₁-C₂₀ alkyl, or R¹ and R² form a substituted or unsubstituted C₁-C₂₀ cycloalkyl ring, and wherein R³, R⁴, R⁵, Rₙ are independently selected from hydrogen, substituted or unsubstituted C₁-C₂₀ alkyl, substituted or unsubstituted C₁-C₂₀ alkoxy, and substituted or unsubstituted C₁-C₂₀ vinyl, and n is an integer from 1 to 3.

In one or more specific embodiments, when the deposition is non-selective, the precursor of Formula (I) is selected from one or more of

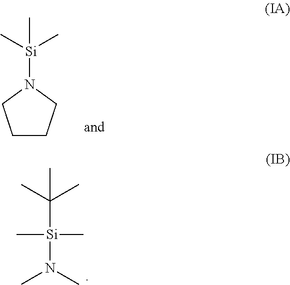

In one or more embodiments, a passivation layer 112 is selectively deposited on the substrate 100 by exposing the substrate 100 to a precursor. In one or more embodiments, the deposition is selective such that the passivation layer 112 forms on the top surface 122 and on the sidewall surface 124 but does not form on the bottom surface 120. In one or more embodiments, when the deposition is selective, the precursor comprises a compound according to Formula (II) and Formula (IV)

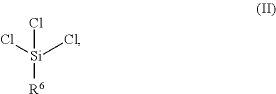

RₙSiX₍₄₋ₙ₎ (IV),

wherein R⁶ and Rₙ are independently selected from hydrogen, substituted or unsubstituted C₁-C₂₀ alkyl, substituted or unsubstituted C₁-C₂₀ alkoxy, and substituted or unsubstituted C₁-C₂₀ vinyl, X is a halide selected from Cl, Br, and I, and n is an integer from 1 to 3.

In one or more specific embodiments, when the deposition is selective, the precursor of Formula (II) is

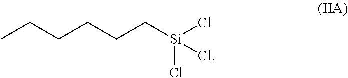

Referring to FIG. 1 and FIG. 2D, at operation 16, in one or more embodiments, the substrate 100 is cleaned. In some embodiments, the cleaning is an etch process. In some embodiments, the etch process may comprise any suitable means, including but not limited to, plasma cleaning processes. In one or more embodiments, the substrate 100 is subjected to a plasma treatment. In some embodiments, the plasma comprises one or more of hydrogen (H₂), nitrogen (N₂), or argon (Ar) plasma. As used in this specification, a plasma comprising hydrogen, nitrogen, or argon, means a plasma formed from the molecular form of the species named. In some embodiments, the plasma consists essentially of hydrogen, nitrogen, argon, or combinations thereof.

The power of the plasma may be varied depending upon the composition, packing, and/or thickness of the materials. In some embodiments, the plasma power is in a range of about 20 W to about 500 W, in a range of about 50 W to about 500 W, in a range of about 100 W to about 500 W, or in a range of about 200 W to about 400 W.

The duration of the plasma exposure may be varied depending on the composition, packing and/or thickness of the materials. In some embodiments, the substrate is exposed to the plasma for a time period in a range of about 2 s to about 60 s, in a range of about 3 s to about 30 s, or in a range of about 5 s to about 10 s. In some embodiments, the substrate is exposed to the plasma for a time period of about 3 s, about 5 s, about 10 s, or about 30 s.

In some embodiments, cleaning the substrate 100 removes the oxide layer 108 from the bottom surface 120 and removes the damaged layer 106 from the top surface 122. Any passivation layer 112 present on the oxide layer 108 and on the damaged layer 106 is also removed during the cleaning. In some embodiments, cleaning the substrate 100 forms a bottom surface 120 and/or a top surface 122 that is substantially free of oxides. As used in this manner, the term “substantially free of oxides” means that there are less than or equal to 5%, 2%, 1% or 0.5% of oxygen atoms on the surface. In one or more embodiments, one or more of anisotropic etching, thermal etching, or plasma etching is used to etch and remove the oxide layer and the damaged layer 106 from the surface. In one or more embodiments, the etching is directional etching. In one or more embodiments, the passivation layer 112 remains on the sidewall surface 124 after etching.

Without intending to be bound by theory, it is thought that depositing a passivation layer 112 using one or more of the precursors described herein reduces the wet etch rate of the silicon nitride layer/silicon oxynitride layer (silicon nitride layer 104/damaged layer 106). In some embodiments, the wet etch rate is reduced by about 5 Å/min, or by about 10 Å/min, or by about 20 Å/min, or by about 30 Å/min, or by about 40 Å/min, or by about 50 Å/min.

With reference to FIGS. 1 and 2E, at operation 18, in subsequent processing of the substrate 100, the substrate 100 may be removed from a processing chamber with a vacuum break. In some embodiments, an oxide layer 116 may form on one or more of the top surface 122 and the bottom surface 120. In some embodiments, the top surface 122 of the silicon nitride layer 104 may be damaged by exposure to oxygen in the atmosphere and a damaged layer 114 may form on a top surface 122 of the silicon nitride layer 104.

In one or more embodiments, referring to FIGS. 1 and 2F, at operation 20, the passivation layer 112, the damaged layer 114, and the oxide layer 116 are removed. Removal may occur by any method known to the skilled artisan including, but not limited to, etching. In one or more embodiments, removal of the passivation layer 112, the damaged layer 114, and the oxide layer 116 exposes the top surface 122, the bottom surface 120, and the sidewall surface 124 of the feature 110. In one or more embodiments, the feature 110 has a width, w₂. In one or more embodiments, because of the use of the passivation layer 112, the width (critical dimension) of the feature 110 is substantially the same as the width, w₁, of the feature prior to formation of the passivation layer 112. As used herein, the term “substantially the same” means that the width varies by less than 10%, less than 5%, less than 4%, less than 3%, less than 2%, or less than 1%. Accordingly, in one or more embodiments, the method 10 advantageously prevents critical dimension enlargement of the feature 110.

In one or more embodiments, the critical dimension width, w₂, of the feature 110 is in a range of from 50 to 100 Å, or is in a range of from 50 to 75 Å, or is in a range of from 60 to 70 Å.

The self-assembled monolayer (SAM) or the passivation layer 112 may be removed by an etch process. In some embodiments, the etch process may comprise any suitable means, including but not limited to, plasma cleaning processes. In one or more embodiments, the self-assembled monolayer (SAM) or the passivation layer 112 is removed by a plasma treatment. In some embodiments, the plasma comprises one or more of hydrogen (H₂), nitrogen (N₂), or argon (Ar) plasma. As used in this specification, a plasma comprising hydrogen, nitrogen, or argon, means a plasma formed from the molecular form of the species named. In some embodiments, the plasma consists essentially of hydrogen, nitrogen, argon, or combinations thereof. In some embodiments, the self-assembled monolayer (SAM) or the passivation layer 112 is removed without causing substantial damage to the silicon nitride layer 104.

The power of the plasma may be varied depending upon the composition, packing, and/or thickness of the self-assembled monolayer (SAM) and composition and/or thickness of the surrounding materials. In some embodiments, the plasma power is in a range of about 20 W to about 500 W, in a range of about 50 W to about 500 W, in a range of about 100 W to about 500 W, or in a range of about 200 W to about 400 W.

The duration of the plasma exposure may be varied depending on the composition, packing and/or thickness of the self-assembled monolayer (SAM) or the passivation layer 112 and composition and/or thickness of the surrounding materials. In some embodiments, the substrate is exposed to the plasma for a time period in a range of about 2 s to about 60 s, in a range of about 3 s to about 30 s, or in a range of about 5 s to about 10 s. In some embodiments, the substrate is exposed to the plasma for a time period of about 3 s, about 5 s, about 10 s, or about 30 s.

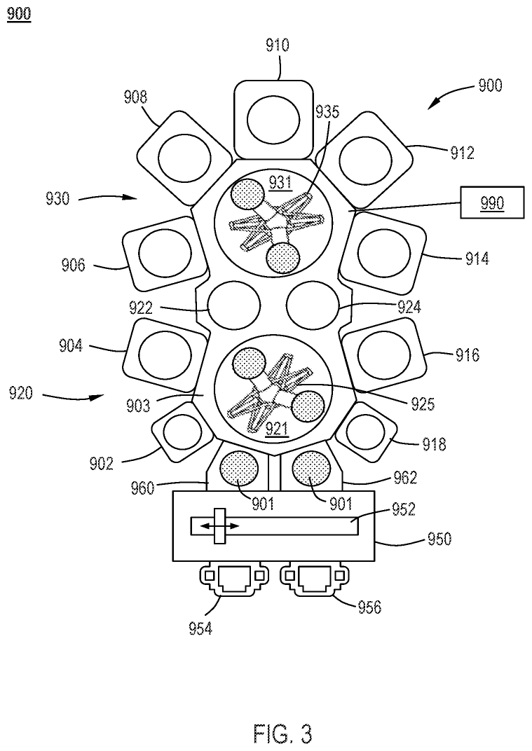

Additional embodiments of the disclosure are directed to processing tools 900 for the formation of the devices and methods described, as shown in FIG. 3. A variety of multi-processing platforms, including the Centura®, Dual ACP, Producer® GT, and Endura® platform, available from Applied Materials® as well as other processing systems may be utilized. In one or more embodiments, the cluster tool 900 includes at least one central transfer station 921, 931 with a plurality of sides. A robot 925, 935 is positioned within the central transfer station 921, 931 and is configured to move a robot blade and a wafer to each of the plurality of sides.

The cluster tool 900 comprises a plurality of processing chambers 902, 904, 906, 908, 910, 912, 914, 916, and 918, also referred to as process stations, connected to the central transfer station. The various processing chambers provide separate processing regions isolated from adjacent process stations. The processing chamber can be any suitable chamber including, but not limited to, a silicon nitride deposition chamber; a PVD deposition chamber; a CVD deposition chamber; a self-assembled monolayer (SAM) deposition chamber; a plasma chamber; a pre-clean chamber; an etching chamber; transfer space(s), a wafer orienter/degas chamber, a cryo cooling chamber, and the like. The particular arrangement of process chambers and components can be varied depending on the cluster tool and should not be taken as limiting the scope of the disclosure.

In one or more embodiments, the cluster tool 900 includes a self-assembled monolayer (SAM) deposition chamber to expose the substrate to a precursor and form a self-assembled monolayer (SAM). In one or more embodiments, the cluster tool 900 includes a pre-cleaning chamber connected to the central transfer station.

In the embodiment shown in FIG. 3, a factory interface 950 is connected to a front of the cluster tool 900. The factory interface 950 includes a loading chamber 954 and an unloading chamber 956 on a front 951 of the factory interface 950. While the loading chamber 954 is shown on the left and the unloading chamber 956 is shown on the right, those skilled in the art will understand that this is merely representative of one possible configuration.

The size and shape of the loading chamber 954 and unloading chamber 956 can vary depending on, for example, the substrates being processed in the cluster tool 900. In the embodiment shown, the loading chamber 954 and unloading chamber 956 are sized to hold a wafer cassette with a plurality of wafers positioned within the cassette.

A robot 952 is within the factory interface 950 and can move between the loading chamber 954 and the unloading chamber 956. The robot 952 is capable of transferring a wafer from a cassette in the loading chamber 954 through the factory interface 950 to load lock chamber 960. The robot 952 is also capable of transferring a wafer from the load lock chamber 962 through the factory interface 950 to a cassette in the unloading chamber 956. As will be understood by those skilled in the art, the factory interface 950 can have more than one robot 952. For example, the factory interface 950 may have a first robot that transfers wafers between the loading chamber 954 and load lock chamber 960, and a second robot that transfers wafers between the load lock 962 and the unloading chamber 956.

The cluster tool 900 shown has a first section 920 and a second section 930. The first section 920 is connected to the factory interface 950 through load lock chambers 960, 962. The first section 920 includes a first transfer chamber 921 with at least one robot 925 positioned therein. The robot 925 is also referred to as a robotic wafer transport mechanism. The first transfer chamber 921 is centrally located with respect to the load lock chambers 960, 962, process chambers 902, 904, 916, 918, and buffer chambers 922, 924. The robot 925 of some embodiments is a multi-arm robot capable of independently moving more than one wafer at a time. In one or more embodiments, the first transfer chamber 921 comprises more than one robotic wafer transfer mechanism. The robot 925 in first transfer chamber 921 is configured to move wafers between the chambers around the first transfer chamber 921. Individual wafers are carried upon a wafer transport blade that is located at a distal end of the first robotic mechanism.

After processing a wafer in the first section 920, the wafer can be passed to the second section 930 through a pass-through chamber. For example, chambers 922, 924 can be uni-directional or bi-directional pass-through chambers. The pass-through chambers 922, 924 can be used, for example, to cryo cool the wafer before processing in the second section 930 or allow wafer cooling or post-processing before moving back to the first section 920.

A system controller 990 is in communication with the first robot 925, second robot 935, first plurality of processing chambers 902, 904, 916, 918 and second plurality of processing chambers 906, 908, 910, 912, 914. The system controller 990 can be any suitable component that can control the processing chambers and robots. For example, the system controller 990 can be a computer including a central processing unit, memory, suitable circuits, and storage.

Processes may generally be stored in the memory of the system controller 990 as a software routine that, when executed by the processor, causes the process chamber to perform processes of the present disclosure. The software routine may also be stored and/or executed by a second processor (not shown) that is remotely located from the hardware being controlled by the processor. Some or all of the method of the present disclosure may also be performed in hardware. As such, the process may be implemented in software and executed using a computer system, in hardware as, e.g., an application specific integrated circuit or other type of hardware implementation, or as a combination of software and hardware. The software routine, when executed by the processor, transforms the general-purpose computer into a specific purpose computer (controller) that controls the chamber operation such that the processes are performed.

In one or more embodiments, the processing tool 900 comprises a central transfer station 921, 931 comprising at least one robot 925, 935 configured to move a wafer; a self-assembled monolayer (SAM) formation station, a CVD station, a PVD station connected to the central transfer station; an optional pre-clean station connected to the central transfer station; and at least one controller connected to the one or more of the central transfer station, self-assembled monolayer (SAM) formation station, a CVD station, a PVD station, or the optional pre-clean station. In one or more embodiments, the at least one controller has at least one configuration selected from: a configuration to move the wafer between stations using the robot; a configuration to expose a substrate to a precursor and form a self-assembled monolayer (SAM); and a configuration to pre-clean the wafer.

Reference throughout this specification to “one embodiment,” “certain embodiments,” “one or more embodiments” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in one embodiment” or “in an embodiment” in various places throughout this specification are not necessarily referring to the same embodiment of the disclosure. Furthermore, the particular features, structures, materials, or characteristics may be combined in any suitable manner in one or more embodiments.

Although the disclosure herein has been described with reference to particular embodiments, those skilled in the art will understand that the embodiments described are merely illustrative of the principles and applications of the present disclosure. It will be apparent to those skilled in the art that various modifications and variations can be made to the method and apparatus of the present disclosure without departing from the spirit and scope of the disclosure. Thus, the present disclosure can include modifications and variations that are within the scope of the appended claims and their equivalents.

What is claimed is:

1. A method of forming a semiconductor structure, the method comprising:
depositing a passivation layer on a substrate, the substrate comprising a silicon nitride layer including at least one feature formed therein, the at least one feature having a first width, a top surface, a bottom surface, and at least one sidewall surface, wherein a damaged silicon nitride layer is on the top surface and on the at least one sidewall surface, and a silicon oxide layer is on the bottom surface; and
pre-cleaning the substrate to remove the damaged silicon nitride layer from the top surface and the silicon oxide layer from the bottom surface.

2. The method of claim 1, wherein the passivation layer is deposited on the top surface, the bottom surface, and on the at least one sidewall surface.

3. The method of claim 1, wherein the passivation layer is selectively deposited on the top surface and on the at least one sidewall surface but not on the bottom surface.

4. The method of claim 1, wherein depositing the passivation layer comprises exposing the substrate to a precursor.

5. The method of claim 4, wherein the precursor comprises a compound according to one or more of a Formula (I), Formula (II), Formula (III), and Formula (IV): 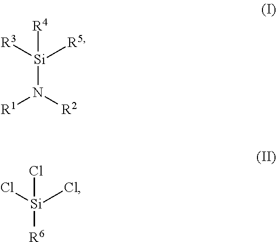
RₙSi(NR′R″)₍₄₋ₙ₎ (III), RₙSiX₍₄₋ₙ₎ (IV),
wherein R¹ and R² are independently selected from substituted or unsubstituted C₁-C₂₀ alkyl, or R¹ and R² form a substituted or unsubstituted C₁-C₂₀ cycloalkyl ring, and
wherein R³, R⁴, R⁵, R⁶, Rₙ are independently selected from hydrogen, substituted or unsubstituted C₁-C₂₀ alkyl, substituted or unsubstituted C₁-C₂₀ alkoxy, and substituted or unsubstituted C₁-C₂₀ vinyl,
X is a halide selected from Cl, Br, and I, and n is an integer from 1 to 3.

6. The method of claim 5, wherein the precursor of Formula (I) is selected from one or more of

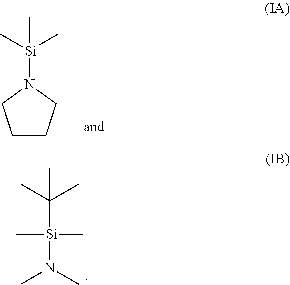

7. The method of claim 5, wherein the precursor of Formula (II) comprises

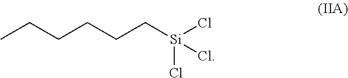

8. The method of claim 1, wherein the at least one feature comprises one or more of a trench and a via.

9. The method of claim 1, further comprising removing the passivation layer from the at least one sidewall surface to expose the silicon nitride layer.

10. The method of claim 9, wherein the at least one feature has a second width that is substantially the same as the first width.

11. The method of claim 10, wherein the first width and the second width are independently in a range of from 60 to 70 Å.

12. A method of forming a semiconductor structure, the method comprising:
depositing a passivation layer on a substrate by exposing the substrate to a precursor, the substrate comprising a silicon nitride layer including at least one feature formed therein, the at least one feature having a first width, a top surface, a bottom surface, and at least one sidewall surface, wherein a damaged silicon nitride layer is on the top surface and on the at least one sidewall surface, and a silicon oxide layer is on the bottom surface; and
pre-cleaning the substrate to remove the damaged silicon nitride layer from the top surface and silicon oxide layer from the bottom surface,
wherein the precursor comprises a compound according to Formula (I) and Formula (III) 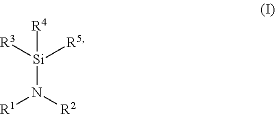
RₙSi(NR′R″)₍₄₋ₙ₎ (III),
wherein R¹ and R² are independently selected from substituted or unsubstituted C₁-C₂₀ alkyl, or R¹ and R² form a substituted or unsubstituted C₁-C₂₀ cycloalkyl ring, and
wherein R³, R⁴, R⁵, and Rₙ are independently selected from hydrogen, substituted or unsubstituted C₁-C₂₀ alkyl, substituted or unsubstituted C₁-C₂₀ alkoxy, and substituted or unsubstituted C₁-C₂₀ vinyl,
and n is an integer from 1 to 3.
wherein R¹ and R² are independently selected from substituted or unsubstituted C₁-C₈ alkyl, or R¹ and R² form a substituted or unsubstituted C₁-C₈ cycloalkyl ring, and
wherein R³, R⁴, and R⁵ are independently selected from hydrogen, substituted or unsubstituted C₁-C₈ alkyl, substituted or unsubstituted C₁-C₈ alkoxy, and substituted or unsubstituted C₁-C₈ vinyl.

13. The method of claim 12, wherein the precursor of Formula (I) is selected from one or more of

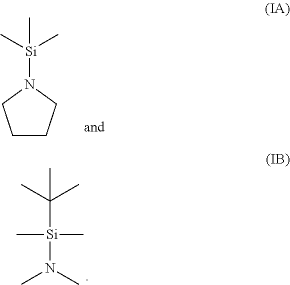

14. The method of claim 12, wherein the at least one feature comprises one or more of a trench and a via.

15. The method of claim 12, further comprising removing the passivation layer and removing the damaged silicon nitride layer from the at least one sidewall surface to expose the silicon nitride layer.

16. The method of claim 15, wherein the at least one feature has a second width that is substantially the same as the first width.

17. The method of claim 16, wherein the first width and the second width are independently in a range of from 60 to 70 Å.

18. A method of forming a semiconductor structure, the method comprising:
selectively depositing a passivation layer on a substrate by exposing the substrate to a precursor, the substrate comprising a silicon nitride layer and including at least one feature formed therein, the at least one feature having a first width and having a top surface, a bottom surface, and at least one sidewall surface, wherein a damaged silicon nitride layer is on the top surface and on the at least one sidewall surface, and a silicon oxide layer is on the bottom surface; and
pre-cleaning the substrate to remove the damaged silicon nitride layer from the top surface and remove the silicon oxide layer from the bottom surface,
wherein the precursor comprises a compound according to Formula (II) and Formula (IV), 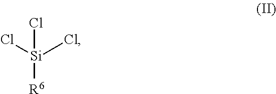
RₙSiX₍₄₋ₙ₎ (IV),
wherein R⁶ and Rₙ are independently selected from hydrogen, substituted or unsubstituted C₁-C₂₀ alkyl, substituted or unsubstituted C₁-C₂₀ alkoxy, and substituted or unsubstituted C₁-C₂₀ vinyl,
X is a halide selected from Cl, Br, and I, and
n is an integer from 1 to 3.

19. The method of claim 18, wherein the precursor of Formula (II) comprises

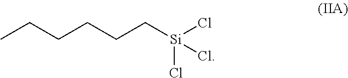

20. The method of claim 18, wherein the passivation layer is selectively deposited on the top surface and on the at least one sidewall surface but not on the bottom surface.

21. The method of claim 18, further comprising removing the passivation layer and removing the damaged silicon nitride layer from the at least one sidewall surface to expose the silicon nitride layer.

22. The method of claim 21, wherein the at least one feature has a second width that is substantially the same as the first width.

23. The method of claim 22, wherein the first width and the second width are independently in a range of from 60 to 70 Å.
